(19) United States
(12) Patent Application Publication
(10) Pub. No.: US 2015/0371930 A1
(43) Pub. Date: Dec. 24, 2015

(54) Integrated Circuit Packaging Method Using Pre-Applied Attachment Medium

(71) Applicant: Texas Instruments Incorporated, Dallas, TX (US)

(72) Inventors: Ruby Ann Maya Merto, Baguio City (PH); Roxanna Bauzon Samson, Benguet (PH)

(21) Appl. No.: 14/307,880

(22) Filed: Jun. 18, 2014

(51) Int. Cl. H01L 23/495; H01L 23/00; H01L 21/56

(52) U.S. Cl. CPC H01L 23/49503; H01L 21/565; H01L 24/83; H01L 23/49541; H01L 24/27; H01L 24/81; H01L 24/91; H01L 2224/2741; H01L 2224/83801; H01L 2224/83192; H01L 2224/73203

(57) ABSTRACT

A method of making an IC package having a die and a substrate that are to be attached at an attachment station including providing the die and substrate and, at a location remote from the attachment station, coating at least one of the die and a die attachment portion of the substrate with attachment medium.

### BACKGROUND

Integrated circuit (“IC”) packages typically comprise at least one die and at least one substrate to which the die is attached by an attachment medium such as solder or epoxy. The substrate facilitates electrical attachment of the die to other electronics, which may be within or outside the IC package. The various components of the IC package are generally encased in a protective mold compound, such as epoxy. A QFN (quad flat no lead) package is one type of integrated circuit package frequently used to package vertically stacked dies. In a QFN package, dies, lead frames and electrical connection clips are arranged in a vertical stack and are interconnected by an attachment medium such as solder or epoxy. The stack is subsequently covered with heated mold compound, which cures to form a hard, box-shaped encasement around the stack. One face of a QFN package typically has a central exposed die attachment pad and a row of exposed lead pads on opposite sides of the die attachment pad. The lead pads allow the QFN to be connected with external circuitry.

During the past decade flip chip technology has emerged as a popular alternative to wire bonding for interconnecting semiconductor devices such as integrated circuit (IC) dies to substrates such as printed circuit boards, carrier substrates and interposers or to other dies.

“Flip chip,” is also known as “controlled collapse chip connection” or its acronym, “C4.” With flip chip technology, solder balls/bumps are attached to electrical contact pads on one face of a die/chip. The flip chip dies are usually processed at the wafer level, i.e., while multiple identical dies are still part of a large “wafer.” Solder balls are deposited on chip pads on the top side of the wafer. The wafer is sometimes “singulated” or “diced” (cut up into separate dies) at this point to provide a number of separate flip chip dies each having solder balls on the top face surface. The chips may then be “flipped” over to connect the solder balls to matching contact pads on the top surface of a substrate, such as a printed circuit board or carrier substrate, on which the flip chip is mounted. Solder ball attachment is usually provided by reflow heating.

As IC dies have become more complex, the number of solder bumps/balls on flip chips have increased dramatically. Whereas in the past the solder balls were usually provided by relatively large round solder balls attached to the chip contact pads, more recently copper pillars (“CuP's”) have been used in place of the solder balls.

A CuP is an elongated copper post member that is attached at one end to a contact pad on the flip chip die. The CuP extends outwardly from the die in a direction perpendicular to the face of the die. Each CuP has a generally bullet or hemisphere shaped solder piece attached to its distal end. The CuP's are bonded by this solder piece to corresponding contact pads on a substrate as by reflow heating.

CuP's are capable of being positioned much more densely, i.e., at a “higher pitch,” than conventional solder balls/bumps. One manner of facilitating connection of a substrate to a die having such high CuP density is to provide bond fingers, rather than conventional contact pads, on the substrate to which the flip chip is to be mounted. The bond fingers are elongated contact pads that may be positioned in close parallel relationship without any insulating material between them. Such a flip chip die and substrate assembly is disclosed in U.S. patent application Ser. No. 13/743,213 of Partosa, et al., for SUBSTRATE WITH BOND FINGERS filed Jan. 16, 2013, Attorney Docket No. TI-71893, which is hereby incorporated by reference for all that it discloses.

### BRIEF DESCRIPTION OF THE DRAWINGS

FIG. 1 is a partially transparent isometric view of an integrated circuit package.

FIG. 2 is a cross-sectional elevation view of the integrated circuit package of FIG. 1.

FIG. 3 is a bottom plan view of the integrated circuit package of FIG. 1.

FIG. 4 is a leadframe strip positioned at an attachment medium coating station remote from a stack assembly station.

FIG. 5 is the leadframe strip of FIG. 4 after coating portions thereof with attachment medium at the attachment medium coating station remote from the stack assembly station.

FIG. 6 is a schematic illustration of various stations at which assembly of an integrated circuit package take place.

FIGS. 7A-7D are schematic representations of various stages in a prior art process of connecting a flip chip die to a substrate having lead fingers.

FIGS. 8A-8D are schematic representations of various stages in applicants' new process of connecting a flip chip die to a substrate having lead fingers.

FIG. 9 is a flow chart of a method of making a QFD package having a QFD stack that is to be assembled at a stack assembly station.

FIG. 10 is a flow chart of a method of making an IC package that is to be assembled at an assembly station.

FIG. 11 is a flow chart of a method of making an IC package having a die and a substrate that are to be attached at an attachment station.

### DETAILED DESCRIPTION

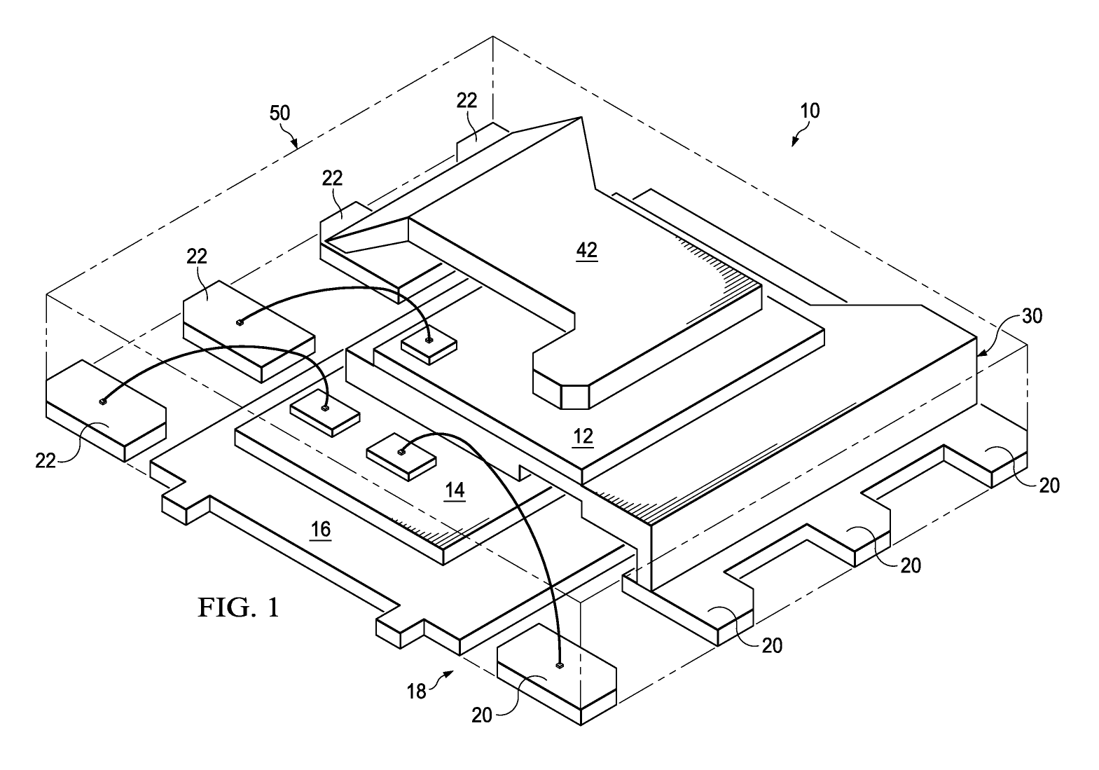

An example integrated circuit package, more specifically a QFN (quad flat no-lead) package 10 that employs stacked die technology is shown in FIGS. 1-3. This QFN package 10 has a high-side MOSFET die 12 (“die 12”) stacked above a low-side MOSFET die 14 (“die 14”).

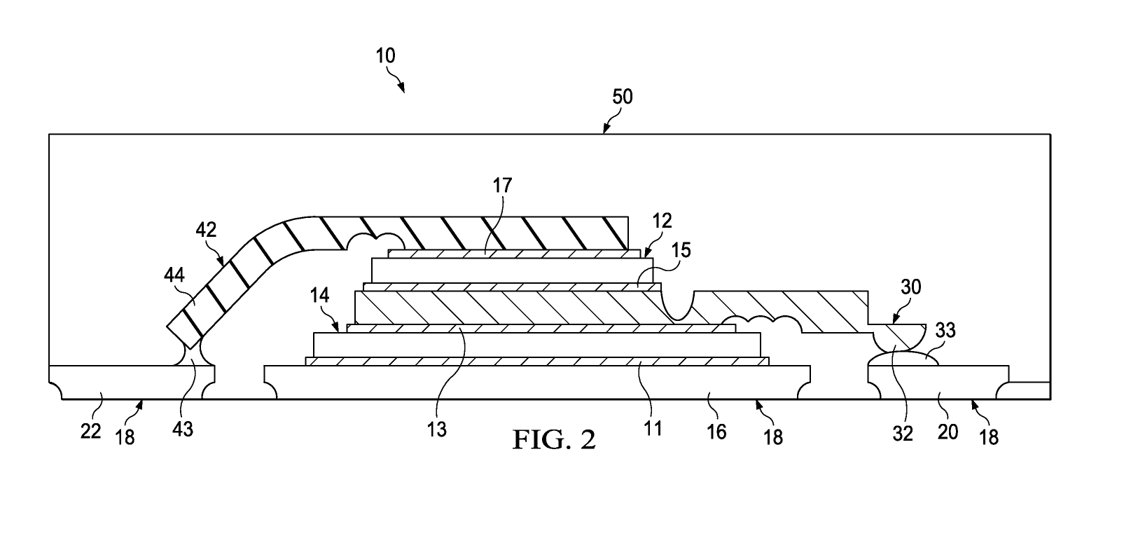

The low-side die 14 is attached to a die attachment pad 16 of a lead frame 18 by a patch of solder 11, FIG. 2. The leadframe 18 has a first plurality of leads 20 on one side of the die attachment pad 16 and another plurality of leads 22 on the opposite side of the die attachment pad 16. The die attachment pad 16 acts as a thermal pad that transfers heat out of the package. The leads 20, 22 are spaced outwardly from the die attachment pad 16. The low-side die 14 is connected to outside electrical circuitry (not shown) through a first copper clip 30 that is attached to die 14 top surface by a patch of solder 13, FIG. 2. The first clip 30 connects the low-side die 14 to some of the first plurality of leads 20. The high-side die 12 is attached to the top surface of the first clip 30 by a patch of solder 15, FIG. 2. A second copper clip 42 connects the high-side die 12 to some of the second plurality of leads 22. The top of the high-side die 12 is attached to the bottom of the second clip 42 by another solder patch 17.

As best shown in FIG. 2 a first end portion 32 of the first clip 30 is attached to some of the first plurality of leads 20 by a plurality of solder patches 33. A first end 44 of the second clip 42 is attached to some of the plurality the leads 22 by a plurality of solder patches 43.

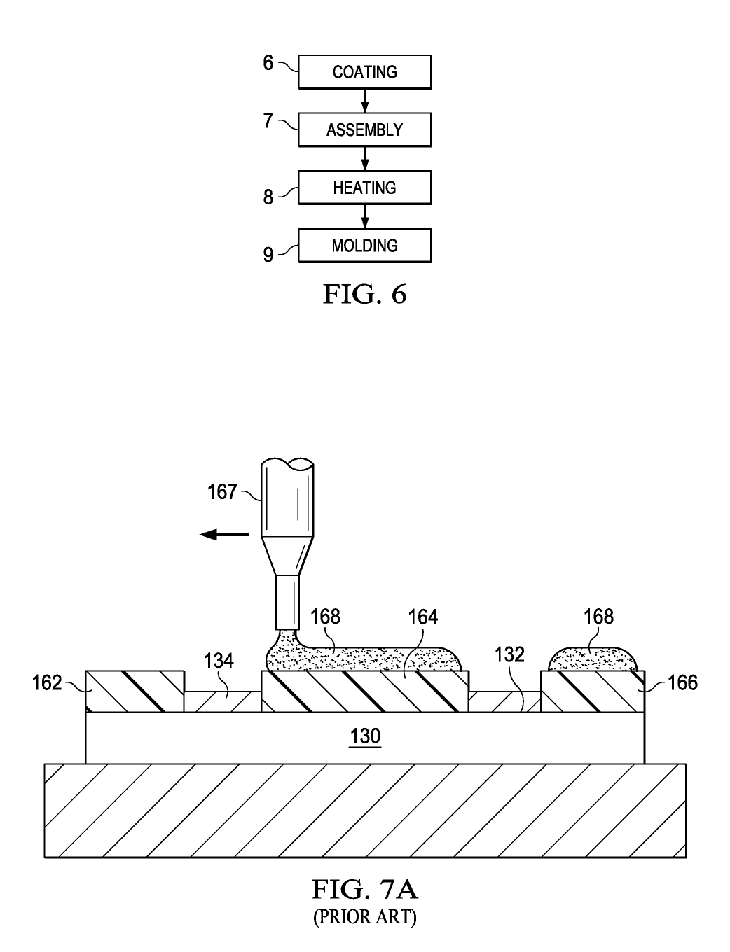

The QFN package 10 has solder patches located at different positions within the QFN package 10. Some of these solder patches may be portions of a conventionally screen-printed layer or all of a conventionally screen printed layer, which may be applied at a stack assembly station when the solder is in paste form. Such solder paste layers may be conventionally applied, one layer at a time, as the stack is built up. However, at least one solder paste layer of the stack of QFN 10 is applied, not at the stack assembly area 7, but at a remote location 6, as shown schematically in FIG. 6.

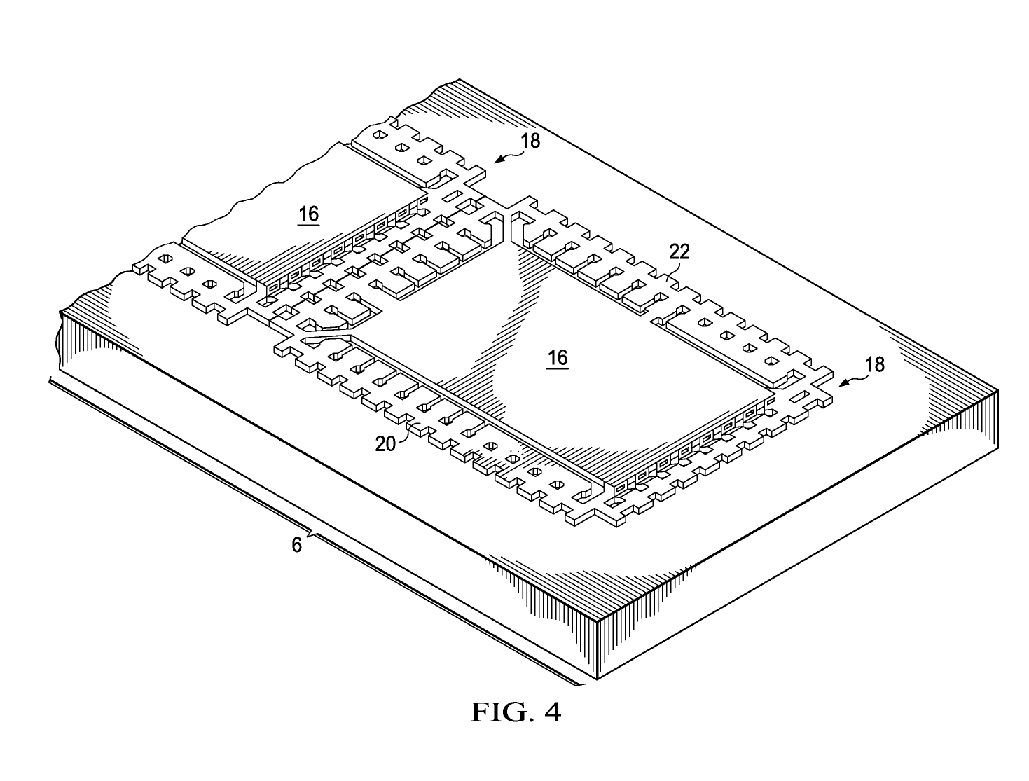

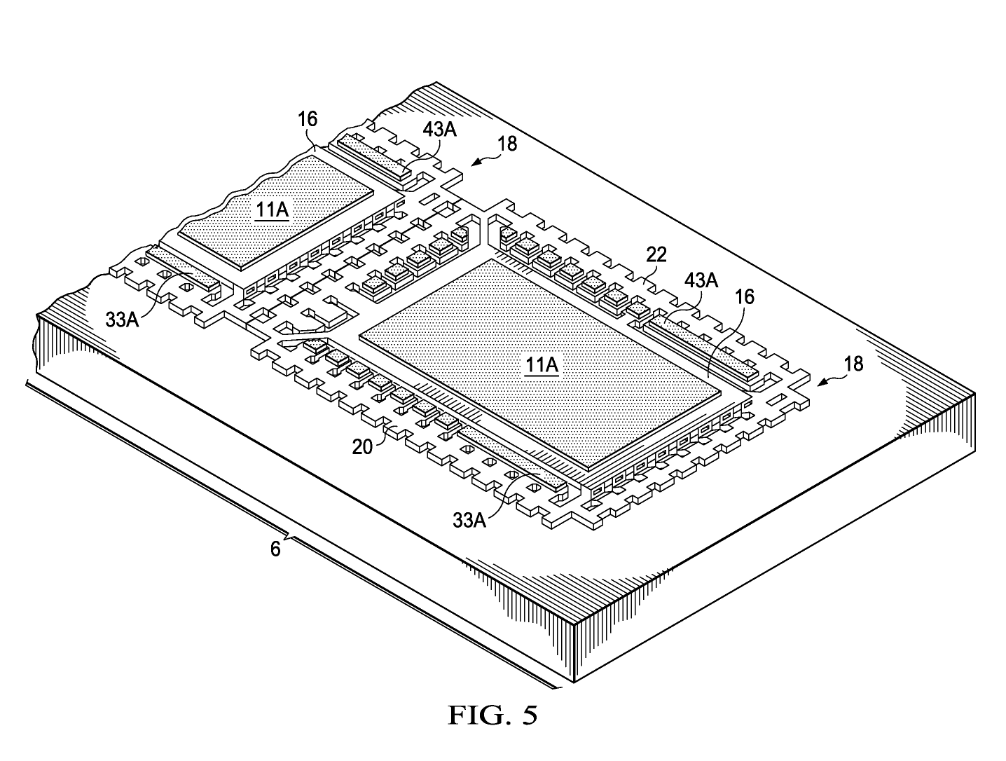

For example, as shown in FIGS. 4 and 5, solder paste patch 11A may be applied to the top surface of the bottom lead frame 18 and solder paste patches 33A and 43A may be applied to the top surfaces of the plurality of leads 20 and 22, respectively, at a remote location 6, such as a leadframe manufacturing facility. In one embodiment the paste patches 11A, 33A and 43A are all portions of the same screen-printed layer of solder paste. After application of this solder paste layer, the at least partially solder paste coated leadframe 18 is moved to the stack assembly area 7, FIG. 6, where stack assembly commences. After the entire stack is built up, it is transferred to a heating station 8, such as reflow furnace, where the solder paste is reflowed and subsequently cooled to form the solid solder bonds illustrated in FIG. 2. Thus, one difference between the stack of the QFN package 10 shown in FIGS. 1-3 and the prior art, is that at least one solder paste layer of QFN package 10, for example the layer providing patches 11A, 33A and 43A, is applied at a location 6 that is remote from the station 7 where stack assembly is performed. In other words, before the leadframe 18 is physically transferred to the stack assembly area 7, it has already been coated with a solder paste layer. This solder paste layer includes solder paste patches 11A, 33A and 43A that become solder patches 11 on the die attachment pad 16 and solder patches 33 on top each of the leads 20 that are attached to the first clip 30 and also solder patches 43 on the leads 22 that are to be attached to the second clip 42. In some QFN embodiments, some or all of the other solder paste layers of the QFN are remotely applied as well. In some other QFN embodiments, these other solder paste layers are applied conventionally at the stack build up site 7. In each case, the assembled stack of the QFN 10 has at least one region where the solder paste is applied at a place 6 remote from the stack assembly area 7. After the stack is fully assembled it is moved to a heating station 8, such as a reflow furnace, where the solder is reflowed.

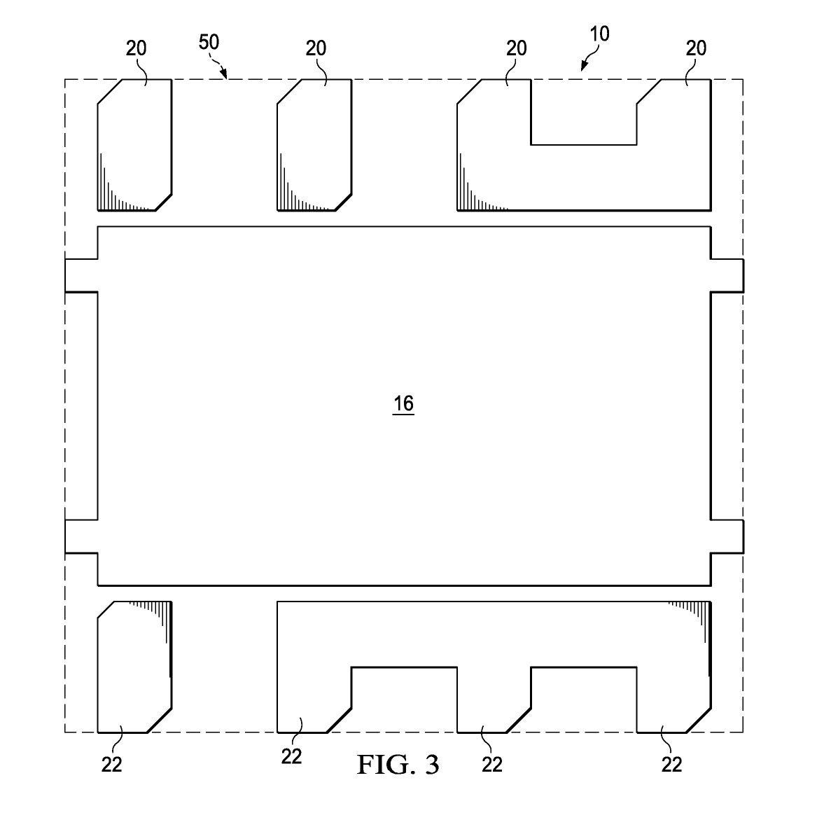

After the solder paste in the stack has been reflowed in the reflow furnace and cooled, the entire stack may be encapsulated in heated mold compound at a molding station 9. This mold compound cools to form a rigid epoxy encasement/box 50 around the stack. As shown by FIG. 3, each of the first and second plurality of leads 20, 22 and the die attachment pad 16 are exposed at the bottom surface of the epoxy box 50.

A substantially similar process to the process described immediately above in which solder paste is the attachment medium, may be performed using epoxy as the attachment medium. The various components of the stack are attached by epoxy patches that are in a paste state. At least one of the epoxy paste layers, e.g., the layer corresponding to patches 11A, 33A and 43A in FIG. 5, is applied at a station 6 remote from the stack assembly station 7. The stack is then moved to a heating station 8. The epoxy paste curing process takes place at a lower temperature and over a different time period than solder reflow. After the attachment epoxy has cured the assembly is encapsulated at molding station 9.

Prior art methods of applying patches of component attachment medium (solder or epoxy) include screen/stencil printing, use of direct dispense guns and ink-jet type applicators, etc., at the stack assembly station as the stack is being built up. Problems with all such prior art methods arise from difficulty in accurately applying the attachment medium to the desired targets in the correct amount at the stack assembly station.

Applicants have discovered that improved attachment bonds may be provided when the attachment medium is applied, at least to the leadframe, at a separate station, remote from the stack assembly station, where medium dispensing can be better controlled both in targeting the area of application and in the amount of medium dispensed. This separate station could be, for example, at the leadframe manufacturer's facility or at another station in the facility where the stack is assembled. Thus, according to one embodiment of this new method, the leadframe is placed in the stack assembly area as an attachment medium pre-coated leadframe. This eliminates the step, used in the conventional method, of applying medium to the leadframe when it is in the stack assembly area. As a result increased production speed and better component bonding may be provided.

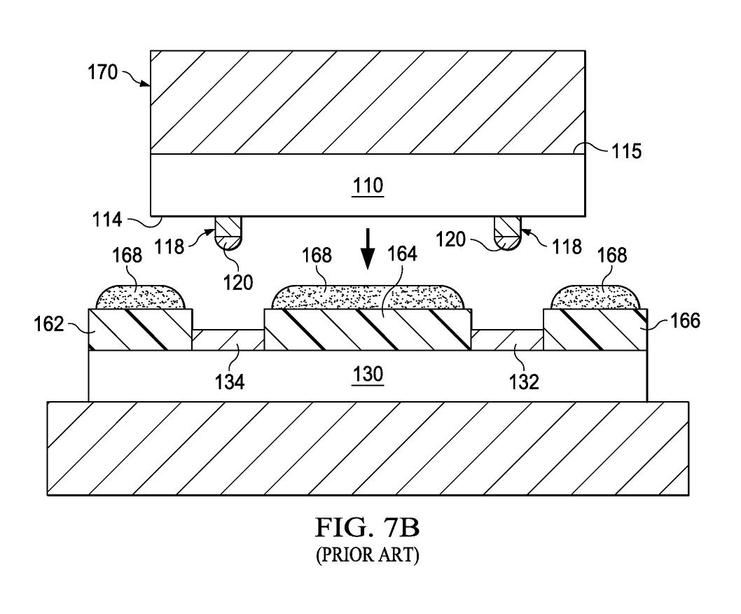

A conventional process by which a flip chip die 110 with copper post connectors 118 is mounted on a substrate 130 is illustrated in FIGS. 7A 7D. Initially, FIG. 7A, a layer of nonconductive paste (“NCP”) 168 is deposited on the upper surface of solder resist layers or strips 162, 164 and 166 as with a conventional, laterally displaceable NCP dispenser 167.

Next, as illustrated in FIG. 7B, a flip chip die 110 with the active face 114 thereof facing downwardly is carried by a die placement and bonding head 170 to a position directly over the substrate 130. The copper post connectors 118 on the die 110 are positioned directly above target areas where the copper post connectors 18 are to be attached to the bond fingers 132, 134, etc. (It is to be understood that typically there are a plurality of copper post connectors 118 and a plurality of bond fingers 132, 134, etc., positioned in spaced apart relationship and extending in respective columns perpendicular to the plane of the drawing in FIGS. 7A-7D.)

Next, FIG. 7C, the placement and bonding head 170 is lowered to position the die 110 in near contact with the top surface of solder resist strips 162, 164, thereby spreading the nonconductive paste (NCP) 168 across the top surface of the solder resist strips 162, 164. At the same time, a solder tip 120 of each copper post connector 118 comes into contact with the targeted area on an associated bond finger, e.g., 132, 134, The die 110 and substrate 130 are maintained in this position under heat and pressure which causes the individual copper post connectors 118 to bond with the associated bond fingers 132, 134, etc., on the substrate 130.

As a final step, as shown in FIG. 7D, the die placement and bonding head 170 is removed leaving a flip chip and substrate assembly 172 that comprises the flip chip die 110 and substrate 130 attached to one another by the solder bonds between the copper post connectors 118 and bond fingers 134, etc. The flip chip die 110 and substrate 130 are also physically bonded by the thin NCP layer 168 between them. This assembly 172 may be a printed circuit (PC) board having a die mounted thereon or an integrated circuit package comprising a flip chip die and substrate assembly, which in some embodiments further comprise a lid over the flip chip die and in some embodiments includes encapsulant covering the flip chip die and substrate. The substrate 130 may also include connectors such as a ball grid array for attaching and electrically connecting the die/substrate package to other circuitry. Other flip chip and substrate assemblies may include a flip chip and interposer or a flip chip and another type of electrical substrate.

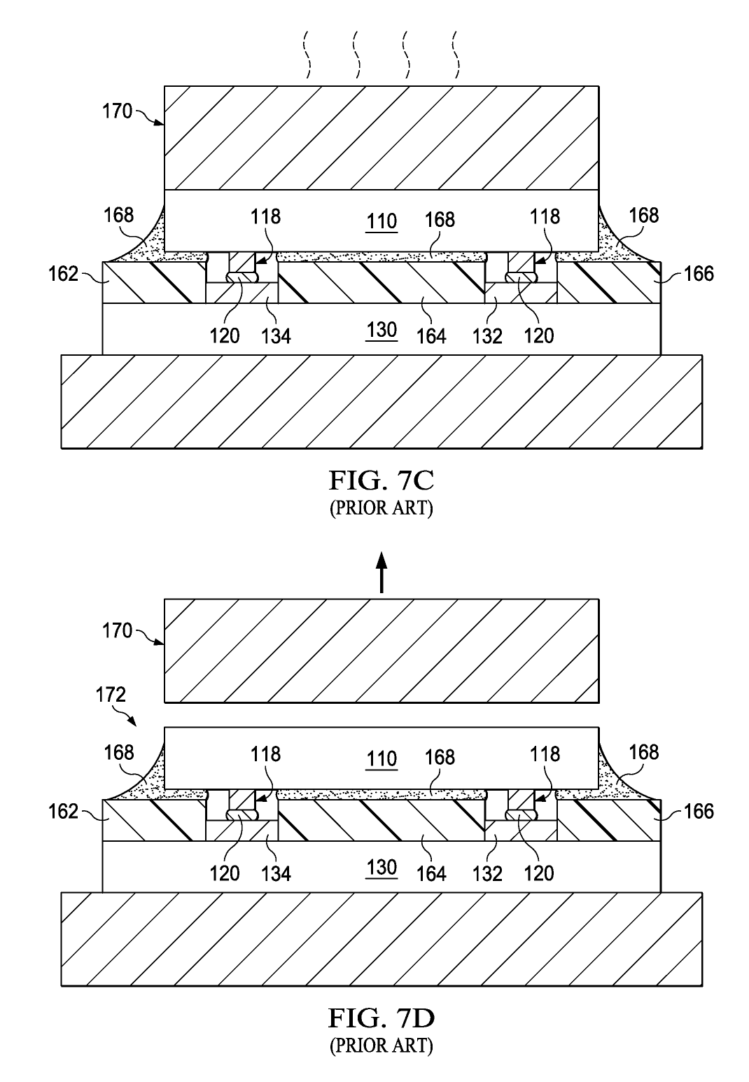

Applicants' new process by which a flip chip die 210 with copper post connectors 218 is mounted on a substrate 230 is illustrated in FIGS. 8A-8D. Initially, FIG. 8A, at a location 290, which is remote from a location 292, FIGS. 8B-8D where the die is attached to the substrate, a layer of nonconductive paste (“NCP”) 268 is deposited on the upper surface of solder resist layers or strips 262, 264 and 266, as with a conventional, laterally displaceable NCP dispenser 267, or other dispenser. The layer of nonconductive paste 268 may be solder paste or other nonconductive attachment medium in paste form such as nonconductive epoxy. By applying the attachment medium at a separate station 290 remote from the die attach station 292, the conditions for paste dispensing may be more carefully controlled than if paste dispense takes place at the die attach station 292. For example attachment medium application could take place at a substrate manufacturing facility. An additional benefit is that the substrate could be shipped to the die attach facility pre-coated with attachment paste. This would eliminate the coating step from the die attach process that is performed at the die attach facility. Eliminating this step may increase the speed and efficiency of the die attach process.

In another embodiment of the new method, a layer of conductive paste 272 is deposited on the upper surface of lead fingers 232, 234, etc., as by a conventional laterally displaceable conductive paste dispenser 274, or other conductive paste dispenser, that is located at station 290, which is remote from the location 292 where the die is attached to the substrate.

Next, as illustrated in FIG. 8B, the substrate 230 is transported from the substrate pre-coating station 290 to the die attachment station 292, which may be located at the same facility or a different facility than the pre-coating station 290. A flip chip die 210 with the active face 214 thereof facing downwardly is carried by a die placement and bonding head 270 to a position directly over the substrate 230. The copper post connectors 218 on the die 210 are positioned directly above target areas where the copper post connectors 218 are to be attached to the bond fingers 132, 134, etc. (It is to be understood that typically there are a plurality of copper post connectors 218 and a plurality of bond fingers 232, 234, etc., positioned in spaced relationship and extending in respective columns perpendicular to the plane of the drawing in FIGS. 8A-8D.)

Next, FIG. 8C, at the die attachment station 292, the placement and bonding head 270 is lowered to position the die 210 in near contact with the top surface of solder resist strips 262, 264, 266 thereby spreading the nonconductive paste (NCP) 268 across the top surface of the solder resist strips 262, 264, 266. At the same time, in one embodiment in which conductive solder paste 272 (or other conductive attachment paste) is applied to conductive finger 232, 234, and in which there may or may not be a solder (epoxy) tip 220 on each copper post connector 218, the distal end of each solder post 218 comes into contact with conductive paste 272 on an associated bond finger, e.g., 232, 234. The die 210 and substrate 230 are maintained in this position under heat and pressure, which causes the conductive paste 272 in one case, and the conductive paste 272 and solder (or epoxy) tip 220 in another case, to bond the individual copper post connectors 218 to the associated bond fingers 232, 234, etc., on the substrate 230. In another embodiment in which no conductive paste 272 is applied to the bond fingers 232, 234, etc. and in which each copper post 218 does have a solder (or epoxy) tip 220, the solder tip 220 alone bonds the copper post 218 to the associated bond finger 232, 234, etc.

As a final step, as shown in FIG. 8D, the die placement and bonding head 270 is removed leaving a flip chip and substrate assembly 272 that comprises the flip chip die 210 and substrate 230 attached to one another by the conductive solder or epoxy bonds between the copper post connectors 218 and bond fingers 232, 234, etc. As previously mentioned, these bonds between bond fingers and copper post connectors may be formed exclusively by attachment medium in tips 220 or exclusively by conductive paste 272 or by a combination of attachment medium in tips 220 and conductive paste 272. The flip chip die 210 and substrate 230 are also physically bonded by the thin NCP layer 268 between them. This assembly 272 may be a printed circuit board having a die mounted thereon or an integrated circuit package comprising a flip chip die and substrate assembly, which in some embodiments further comprise a lid over the flip chip die and in some embodiments includes encapsulant covering the flip chip die and substrate. The substrate 230 may also include connectors such as a ball grid array for attaching and electrically connecting the die/substrate package to other circuitry. Other flip chip and substrate assemblies may include a flip chip and interposer or a flip chip and another type of electrical substrate.

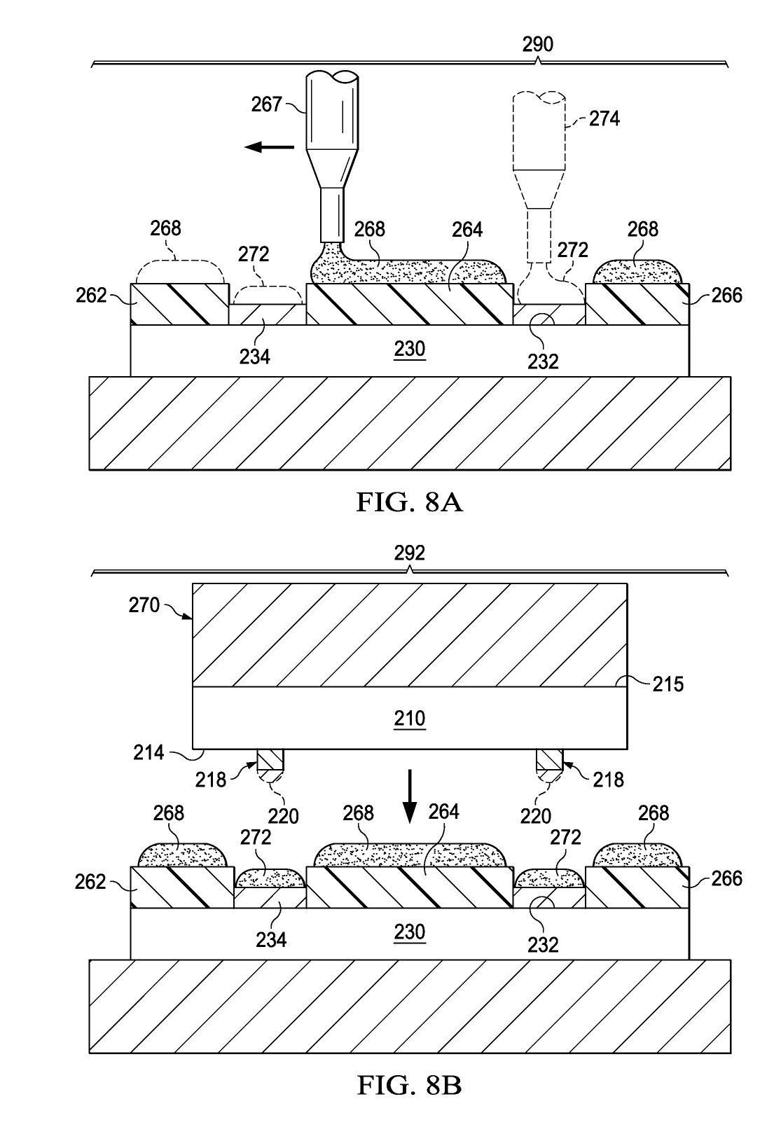

FIG. 9 is a flow chart of a method of making a QFD package having a QFD stack that is to be assembled at a stack assembly station. The method includes providing a leadframe for the QFD, as shown at 301 and, at a location remote from a QFN stack assembly station, coating at least a portion of the leadframe with attachment medium to provide a coated leadframe, as shown at 302.

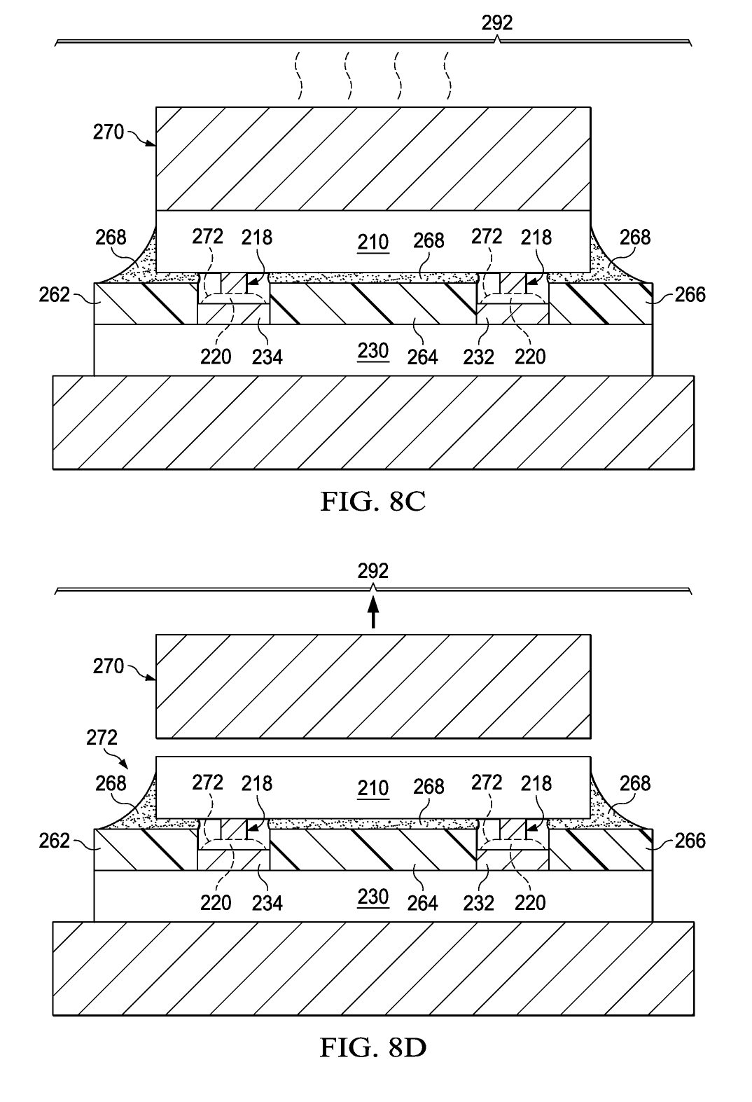

FIG. 10 is a flow chart of a method of making an IC package that is to be assembled at an assembly station. The method includes, as shown at 311, providing a leadframe for the IC package; and, as shown at 312, at location remote from the assembly station, coating at least a portion of the leadframe with attachment medium to provide a coated leadframe.

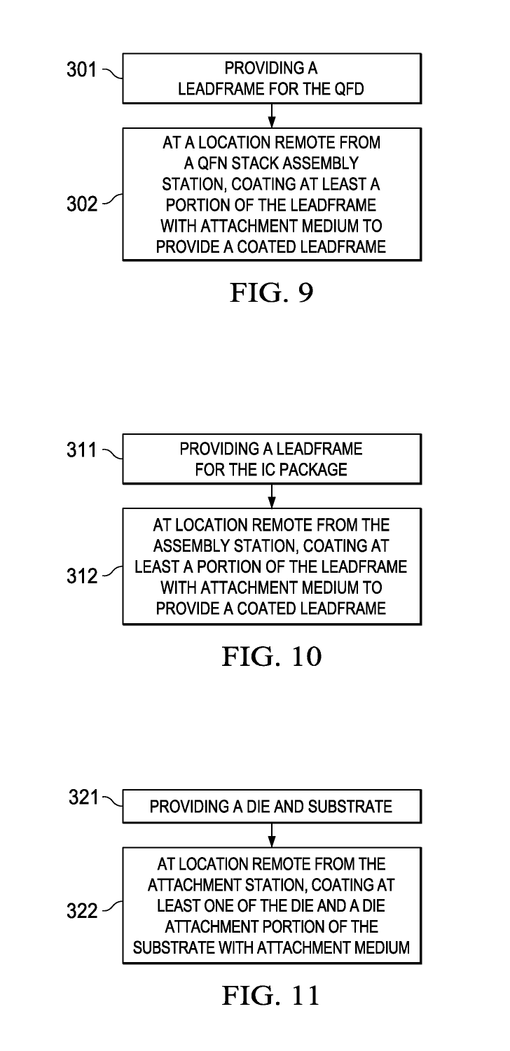

FIG. 11 is a flow chart of a method of making an IC package having a die and a substrate that are to be attached at an attachment station. The method includes providing a die and substrate, as shown at 321 and, at a location remote from the attachment station, coating at least one of the die and a die attachment portion of the substrate with attachment medium, as shown at 322.

Although certain specific embodiments of methods for assembling components of IC packages have been described in detail herein, alternative embodiments will be obvious to those skilled in the art after reading this disclosure. The appended claims are intended to be construed broadly to cover all such alternative embodiments, except as limited by the prior art.

1. A method of making a QFD package having a QFD stack that is to be assembled at a stack assembly station comprising:
providing a leadframe for the QFD; and
at a location remote from a QFN stack assembly station, coating at least a portion of the leadframe with attachment medium to provide a coated leadframe.

2. The method of claim 1 further comprising:
moving the coated leadframe to the stack assembly station; and
mounting a die on the coated leadframe at the stack assembly station.

3. The method of claim 2, further comprising completing assembly of the QFD stack at the stack assembly station.

4. The method of claim 3, further comprising
heating then cooling the assembled stack; and
encapsulating the heated stack in mold compound.

5. The method of claim 1 wherein said at a location remote from a QFN stack assembly station coating at least a portion of the leadframe with attachment medium comprises coating at least a portion of a die attachment pad of the leadframe with attachment medium.

6. The method of claim 1 wherein said at a location remote from a QFN stack assembly station coating at least a portion of the leadframe with attachment medium comprises coating at least a portion of at least one lead of the leadframe with attachment medium.

7. The method of claim 1 wherein said at a location remote from a QFN stack assembly station coating at least a portion of the leadframe with attachment medium comprises coating at least a portion of the leadframe with solder paste.

8. The method of claim 1 wherein said at a location remote from a QFN stack assembly station coating at least a portion of the leadframe with attachment medium comprises coating at least a portion of the leadframe with epoxy.

9. A method of making a IC package that is to be assembled at an assembly station comprising:
providing a leadframe for the IC package; and
at a location remote from the assembly station, coating at least a portion of the leadframe with attachment medium to provide a coated leadframe.

10. The method of claim 9 further comprising:
moving the coated leadframe to the assembly station; and
mounting a die on the coated leadframe at the assembly station.

11. The method of claim 9, further comprising
heating then cooling the assembled die and leadframe; and
encapsulating the die and leadframe in mold compound.

12. The method of claim 9 wherein said at a location remote from the assembly station, coating at least a portion of the leadframe with attachment medium comprises coating at least a portion of a die attachment pad of the leadframe with attachment medium.

13. The method of claim 9 wherein said at a location remote from the assembly station, coating at least a portion of the leadframe with attachment medium comprises coating at least a portion of at least one lead of the leadframe with attachment medium.

14. The method of claim 9 wherein said at a location remote from the assembly station, coating at least a portion of the leadframe with attachment medium comprises coating at least a portion of the leadframe with solder paste.

15. The method of claim 9 wherein said at a location remote from the assembly station, coating at least a portion of the leadframe with attachment medium comprises coating at least a portion of the leadframe with epoxy paste.

16. A method of making an IC package having a die and a substrate that are to be attached at an attachment station comprising:
providing a die and substrate; and
at a location remote from the attachment station, coating at least one of the die and a die attachment portion of the substrate with attachment medium.

17. The method of claim 16 wherein said coating comprises coating with at least one of solder paste and epoxy paste.

18. The method of claim 16 wherein said coating comprises coating the substrate with both a conductive and a nonconductive paste.

19. The method of claim 16:
wherein said providing a die comprises providing a flip chip die and
wherein said coating comprises:
coating a die attachment portion of the substrate with nonconductive attachment paste; and
coating at least one lead finger portion of the substrate with conductive attachment paste.

20. The method of claim 16 further comprising:
moving the die and the substrate to the attachment station;
at the attachment station, attaching at least a portion of the die to the die attachment portion of the substrate and attaching at least one copper post connector extending from the die to the at least one lead finger portion of the substrate.
